(19) United States
(12) Patent Application Publication
(10) Pub. No.: US 2025/0209229 A1
(43) Pub. Date: Jun. 26, 2025

(54) DEVICES, SYSTEMS, AND METHODS FOR CELLULAR STRUCTURE

(71) Applicants: VOLKSWAGEN AKTIENGESELLSCHAFT, Wolfsburg (DE); UNIVERSITY OF TENNESSEE RESEARCH FOUNDATION, Knoxville, TN (US)

(72) Inventors: Megan HARDY, San Francisco, CA (US); Gianina Alina NEGOITA, San Leandro, CA (US); Wesley TESKEY, Foster City, CA (US); Edward MICHAUD, Knoxville, TN (US); Dayakar PENUMADU, Knoxville, TN (US)

(21) Appl. No.: 18/391,116

(22) Filed: Dec. 20, 2023

(51) Int. Cl. G06F 30/15; B62D 65/00; G06T 5/70; G06T 17/20; G06T 19/20

(52) U.S. Cl. CPC G06F 30/15; B62D 65/00; G06T 5/70; G06T 17/20; G06T 19/20; G06T 2219/2021

(57) ABSTRACT

Devices, systems, and methods related to design of structural portions of a vehicular component can include estimating noise within a 3D noise tensor via a 3D denoising-diffusion model and removing noise from the 3D noise tensor based on the estimated noise. Structural portions can be generated including a 3D cellular structure. Design of the vehicular component can be adapted based on the generated structural portion.

### FIELD

The present disclosure relates to devices, systems, and methodologies for component design using cellular structures. More particularly, the present disclosure relates to devices, systems, and methodologies for vehicular component design using cellular structures, and even more particularly, vehicular component design using cellular structures via neural networks.

Cellular structures in component design can afford robust performance with efficiency in mind. Performance properties for mechanical or other functions of a component can be targeted, for example, appropriate strength, compression, and/or rigidity in particular dimensions, while reducing the weight and/or overall material quantity of the component. Other performance properties, such as electromagnetic influence (i.e., shielding, inductive coupling, etc.), heat resistance/conduction, or target thermal transport, and/or other properties may also be targeted while reducing material demands. Yet, development of appropriate geometrics for cellular structure, let alone tailored structures, can be burdensome on time, resources, personnel, and/or can require precise expertise. Ease and/or availability of appropriate cellular structures for component design can assist in reducing design burdens.

### SUMMARY

According to an aspect within the present disclosure, a method of designing a structural portion of a vehicular component may include providing a three-dimensional (3D) noise tensor and at least one desired property of the vehicular component; entering the tensor and the at least one desired property as input into a 3D denoising-diffusion model; estimating noise within the 3D noise tensor via the 3D denoising-diffusion model as an output; removing noise from the 3D noise tensor based on the estimated noise, and generating the structural portion of the vehicular component including a 3D cellular structure having the at least one desired property based on the denoised tensor. The method may further include adapting design of the vehicular component based on the generated structural portion.

In some embodiments, providing the 3D noise tensor may include providing a tensor having at least partial diffusion. The at least one desired property may include at least one definitional parameter. The at least one definitional parameter may include at least one of volume fraction and strength.

In some embodiments, the at least one definitional parameter may include a base shape of the structural portion. The at least one desired property may be provided as a conditional vector having concatenated scalars defining the at least one definitional parameter. The conditional vector may be a float vector.

In some embodiments, the 3D noise tensor may be a 3D Gaussian noise tensor. Estimating noise and removing noise may comprise iteratively estimating and removing noise for each time step based on a predetermined noise distribution. The 3D denoising-difussion model may be defined as a 3D residual U-net.

In some embodiments, providing the 3D noise tensor may include providing a voxelized tensor and adding noise. Providing the 3D noise tensor may include converting a finite element mesh of a known cellular solid structure into a 3D voxelized structure and generating the 3D noise tensor as a voxelized tensor based on the 3D voxelized structure.

According to another aspect of the present disclosure, a system for vehicular component design may include a control system including at least one processor configured for executing instructions stored on memory to conduct operations including: providing a three-dimensional (3D) noise tensor and at least one desired property of the vehicular component; entering the tensor and the at least one desired property as input into a 3D denoising-diffusion model; estimating noise within the 3D noise tensor via the 3D denoising-diffusion model as an output; removing noise from the 3D noise tensor based on the estimated noise, and generating the structural portion of the vehicular component including a 3D cellular structure having the at least one desired property based on the denoised tensor. In some embodiments, the system may further conduct adapting design of the vehicular component based on the generated structural portion.

In some embodiments, providing the 3D noise tensor may include providing a tensor having at least partial diffusion. The at least one desired property may include at least one definitional parameter. The at least one definitional parameter may include at least one of volume fraction and strength.

In some embodiments, the at least one definitional parameter may include a base shape of the structural portion. The at least one desired property may be provided as a conditional vector having concatenated scalars defining the at least one definitional parameter. The conditional vector may be a float vector. In some embodiments, estimating noise and removing noise may comprise iteratively estimating and removing noise for each time step based on a predetermined noise distribution.

Additional features of the present disclosure will become apparent to those skilled in the art upon consideration of illustrative embodiments exemplifying the best mode of carrying out the disclosure as presently perceived.

### BRIEF DESCRIPTION OF THE DRAWINGS

The detailed description particularly refers to the accompanying figures in which:

FIG. 1 is diagrammatic view of operations for design of a structural portion of a vehicular component, according to illustrative embodiments within the present disclosure;

FIG. 2 is a diagrammatic view of the operations of FIG. 1 indicating application of a denoising-diffusion probabilistic model, according to illustrative embodiments within the present disclosure;

FIG. 3 is a diagrammatic view of the denoising-diffusion model of FIG. 2 indicating the model as a 3D residual U-net, according to illustrative embodiments within the present disclosure; and

FIG. 4 is diagrammatic view indicating an illustrative example of training operations concerning the model of FIGS. 1-3, according to illustrative embodiments within the present disclosure.

### DETAILED DESCRIPTION OF THE DISCLOSED EMBODIMENTS

As demand for light vehicles increases, whether to reduce energy consumption in travel or otherwise, vehicular component designs applying three dimensional cellular structures can provide pathways for component design with appropriate performance while conserving materials and/or overall weight.

For example, electric-powered transportation vehicles (EVs) which use electricity for motive power often include on-board power storage. Whether combined with other power sources, such as combustion engines or fuel-cells, or implemented alone, on-board chemical battery storage can provide reliable electric power to drive the transportation vehicle but can face challenges of high density materials driving a significant weight factor.

Additionally, as the EV technologies advance in the market place, performance demands grow, for example, to increase transport range and/or reduce frequency of charging, which can require increased battery mass in existing designs. Similarly, lower-cost materials can have lower densities, creating a sliding-scale of economics and performance. Corresponding increases in demands of supporting components, such as mechanical supports for the batteries, maintenance equipment, and/or safety configurations can follow. Of course, similar design improvements can enhance components other than EV power storage components.

Accordingly, cellularized underlying component structures can assist in obtaining the performance desired, while reducing material and/or weight of the designs. However, design appropriate cellular structures with optimization targeted for a given function (structural, thermal, electro-magnetic or its combination) for given component application can be costly, time-consuming, and/or resource intensive, and thus, easing the application of such cellular structures for given components can yield related design benefits.

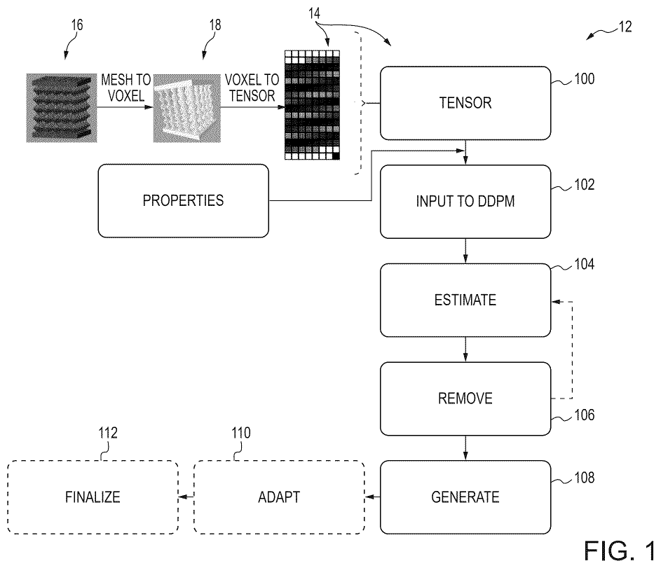

Referring to FIG. 1, operations 12 are indicated diagrammatically concerning component design using three dimensional (3D) cellular structure in terms of boxes 100-112. In the illustrative embodiment, the operations apply a 3D denoising-diffusion model to remove noise from a given structure for generating a new 3D structure for the component design.

In box 100, a 3D tensor 14 is provided. The tensor 14 is illustratively embodied as a 3D noise tensor as suggested in FIG. 1. In the illustrative embodiment, the 3D noise tensor 14 is defined as a voxelized tensor corresponding with a given 3D baseline structure. The 3D baseline structure is illustratively embodied as a finite element mesh 16 comprising a network of interrelated geometric elements corresponding to the underlying structure of a baseline design, which may be traditionally applied in finite element analysis for component design evaluation.

The baseline mesh 16 is illustratively voxelized to provide voxelized structure 18. In the illustrative embodiment, the baseline mesh 16 is embodied as a primitive cellular structure that is converted into the voxelized structure 18 as a 3D voxelized structure of size 128×128×128. In some embodiments, any suitable size configuration, such as 256, 512, 1024, 2048 configurations may be applied. The voxelized structure 18 is illustratively represented in or converted into tensor form, having material absence represented by integer ‘0’ and presence by integer ‘1’.

The 3D tensor 14 is illustratively represented by 128 images of size 128×128. As discussed in additional detail herein, noise is added to the voxelized tensor to provide the 3D tensor 14.

In box 102, the 3D noise tensor 14 is entered as input to a model. As discussed in additional detail herein, the model is illustratively embodied as a 3D denoising-diffusion probabilistic model for assisting the design generation. Desired properties are illustratively entered as input to the model with the 3D noise tensor 14.

In box 104, noise is estimated within the 3D noise tensor 14. The noise estimation is illustratively generated by the model as an output. In box 106, noise is removed from the 3D noise tensor 14 based on the noise estimation.

In the illustrative embodiment, the noise estimation and removal operations of boxes 104, 106 are applied iteratively for denoising via the trained model. In box 108, a structural portion is generated including the resultant 3D cellular structure from iterative application of boxes 104, 106. For example, the structural portion can include a cellular structure distinct from the 3D baseline structure and conditioned or adapted to achieve the desired properties as provided; such as a non-conforming cellular geometric shape adapted from an original conventional diamond cellular structure. A component design can, thus, be generated based on this new structural portion. In some embodiments, new cellular structures targeted for a function optimizing a given variable can further be constrained to additional criteria to yield an acceptable structure that avoids instabilities, for example, buckling and/or rippling under stress.

Optionally, in box 110, an earlier design for a vehicular component can be adapted based on the generated structural portion. In the illustrative embodiment, the underlying 3D cellular structure can be applied to an earlier design such that the dimensions of the vehicular component are adjusted accordingly.

Optionally, in box 112, the vehicular component design may be finalized. Finalization may occur upon acceptable performance criteria which can result from testing or other analysis of the adapted design. For example, threshold performance criteria may be evaluated and confirmed for mechanical strength via finite element analysis of the adapted design.

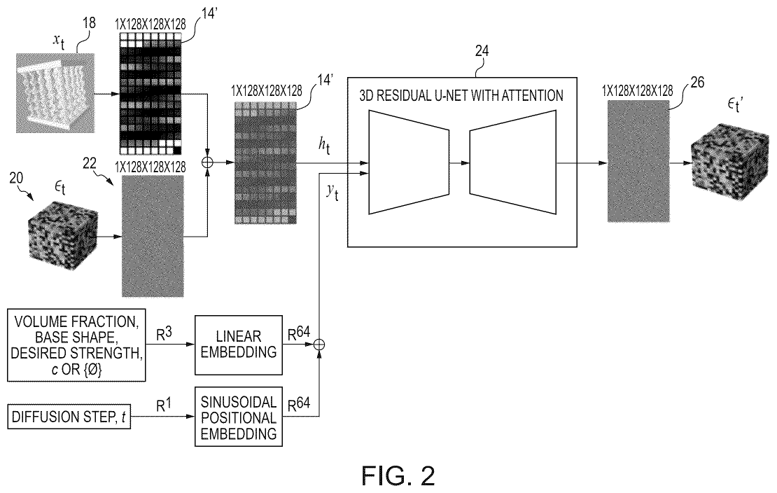

Referring now to FIG. 2, input to the model is illustrated with additional detail. The 3D tensor 14 is provided from the voxelized structure 18, and the 3D tensor 14 is partially diffused into a partially diffused sample 14′. Random noise 20 is sampled from a normal distribution ε in N(0,1) to provide a random noise tensor 22. The random noise tensor 22 is added to the 3D tensor 14 to provide the partially diffused sample as the effective 3D noise tensor 14′ for input to the model 24.

Contextual information is added relative to the component design. In the illustrative embodiment, contextual information includes the desired properties for the generated 3D cellular structure. For example, in the illustrative embodiment, volume fraction, strength, base shape are defined as desired properties. Base shape is illustratively represented by a one-hot vector in [symbol] indicating if the structure is a variation of primitive, gyroid, or diamond baseline structures.

In the illustrative embodiment, volume fraction and strength are each represented as scalar values, that are concatenated channel-wise with the base shape one-hot vector to generate a conditional vector in [symbol] . In the illustrative embodiment, the conditional vector forms a float, non-binary, vector. The conditional vector is embedded to match with the channel size of the model, illustratively by applying a dense layer without bias.

A time diffusion step t is illustratively embedded by sinusoidal embedding via dense layer. Sinusoidal embedding is illustratively followed by a sigmoid linear unit, and another dense layer. The embedded conditional vectors and embedded time vector are summed into a single information vector, y.

The information vector y is illustratively added to the input of the residual blocks throughout the model 24. In the illustrative embodiment, before each residual block undergoes another embedding, a sigmoid linear unit is added followed by a dense layer. This embedding reshapes the information vector y to correspond with the 3D noise tensor 14′. Accordingly, the 3D noise tensor 14′ and the reshaped information vector y can be summed and entered as the input 3D noise tensor 14′ to the residual block.

In the illustrative embodiment as shown in FIG. 2, the model 24 is embodied as a denoising-diffusion probabilistic model based on a convolution neural network, embodied as a 3D residual U-net neural network. Encoding and decoding is conducted as discussed in additional detail herein. The model 24 provides noise estimation 26 as an output which corresponds to a noise estimation εₜ′.

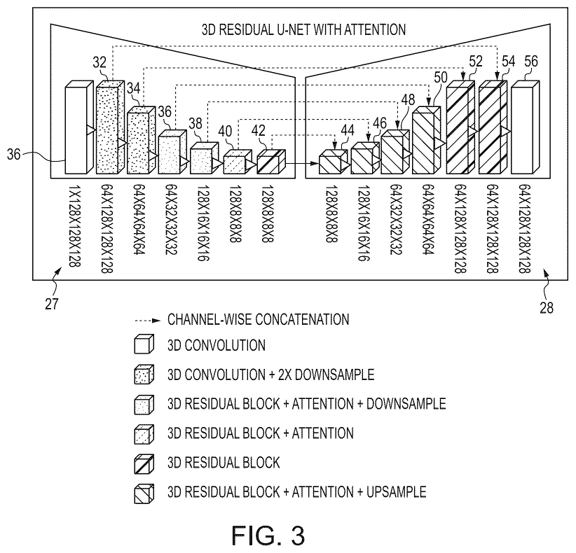

Referring to FIG. 3, the model 24 is shown with additional detail for descriptive ease. The model 24 illustratively includes encoder 27 and decoder 28 portions for conducting U-net operations. In the illustrative embodiment, three downsampling/upsampling steps are conducted, although in some embodiments, any suitable number of downsampling/upsampling steps may be applied.

In the illustrative embodiment as shown in FIG. 3, from highest to lowest resolution, channels (c, c, 2c, 2c) are applied, where c=64. One 3D convolutional residual block is illustratively considered per resolution, and multi-head self-attention with 4 heads, used at 16×16 resolution and 8×8 resolution is applied. Residual blocks carry residual function with reference to the layer input.

Upsampling is illustratively conducted via nearest-neighbor algorithm followed by a 3D convolution, and is illustratively conducted two times in all three spatial dimensions (length, width, height). In the illustrative embodiment, the data is shaped as channels×length×width×height.

Channel-wise concatenation is conducted between the corresponding levels of the encoder portion 27 and decoder portion 28, as suggested in FIG. 3 via broken line connection. In the encoder 27, 3D convolution is conducted at 30. 3D convolution and two levels of downsampling is conducted at 32, 34. 3D residual block with attention and downsampling is conducted at each of 36, 38. 3D Residual block with attention is applied at 40, and 3D residual block is applied at 42.

In the decoder portion 28, 3D residual block with attention and upsampling is conducted at each of 44, 46, 48, 50. At each of 52, 54, residual block is applied. 3D convolution is conducted at 56.

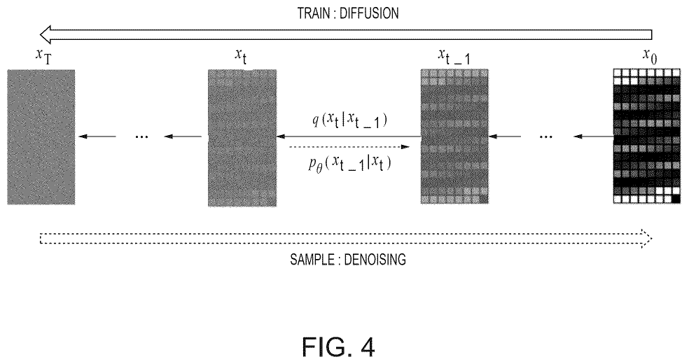

Referring now to FIG. 4, in the illustrative embodiment moving leftward, training of the neural network is conducted by recovering data from training data that has incurred successive addition of Gaussian noise. Noise is iteratively added to the training data. T times, such that xₜ=xₜ₋₁+εₜ₋₁. Noise ε is estimated ε′, and the model is illustrative trained with mean-squared error loss ∥ε, ε′∥².

Sampling occurs from a known distribution q(xₜ|xₜ₋₁), as suggest in FIG. 4. Estimating εₜ from each time step in [0, . . . , T], estimated noise can be removed iteratively, estimating the data distribution at time, t−1: p_{θ}(xₜ|xₜ₋₁). Accordingly, training data is decayed through addition of Gaussian noise, and recovered by reversing the noising process.

Once trained, data can be generated matching the data distribution p_{θ}(x_{θ}). As suggested in FIG. 4, a random noise tensor is input into the model as xₜ, and, moving rightward, noise is iteratively estimated and subtracted according to:

$${X}_{T - 1}^{′} = {X}_{T} - {ε}_{T}^{′}$$

$${X}_{T - 2}^{′} = {X}_{T - 1} - {ε}_{T - 1}^{′}$$

$$…$$

$${X}_{0}^{′} = {X}_{1} - {ε}_{1}^{′}$$

In the illustrative embodiment, training hyper parameters were selected including a linear noise scheduler with T=100 diffusion steps, and the loss-second-moment schedule sample. Loss is illustratively applied as mean-squared-error, as previously mentioned; gradient-based optimization is applied, such as Adam optimizer, using weight decay of 1E-07, learning rate of 1E-05, and beta values (0.99, 0.999); and dropout with probability of p=0.02 is applied.

After each interval of 100 training iterations, an empty set vector in passed in place of the conditional vector c, known as classifier-free diffussion. In illustrative embodiments, about 50 training structure tensors incur erosion and dilation with kernal sizes of 3×3 and 5×5 to increase training data size by a factor of 4. In some embodiments, any suitable techniques may be applied, for example, for diffusion, loss, and/or optimization, and/or conditioning operations.

Accordingly, within the present disclosure vehicular components can be designed with 3D cellular structure generated by denoising-deffusion techniques to enhanced in one or both of qualitative and quantiative performance in design efforts. For example, using micro and meso structures of solid fraction inspired by highly rigorous mathematical surfaces such as Triply Periodic Minimal Surfaces (TPMS), desireable cellular structures can be generated for particular component application. The present disclosure includes operation of machine learning and/or generative artificial intellegence modules, which can include execution of instructions stored on memory by one or more processors to conduct such operations, and may include communication circuitry to communicate governing and/or facilitating signals to and/or from other devices and/or systems. Model parallelization can be applied, for example, using two v100 GPUs with a batch size of 1.

Examples of suitable processors may include one or more microprocessors, integrated circuits, system-on-a-chips (SoC), among others for executing instructions stored on memory. Examples of suitable memory, may include one or more primary storage and/or non-primary storage (e.g., secondary, tertiary, etc. storage); permanent, semi-permanent, and/or temporary storage; and/or memory storage devices including but not limited to hard drives (e.g., magnetic, solid state), optical discs (e.g., CD-ROM, DVD-ROM), RAM (e.g., DRAM, SRAM, DRDRAM), ROM (e.g., PROM, EPROM, EEPROM, Flash EEPROM), volatile, and/or non-volatile memory; among others.

Communication circuitry for facilitating communications with the processor may include components for facilitating processor operations, for example, suitable components may include transmitters, receivers, modulators, demodulators, filters, modems, analog/digital (AD or DA) converters, diodes, switches, operational amplifiers, and/or integrated circuits.

Although certain embodiments have been described and illustrated in exemplary forms with a certain degree of particularity, it is noted that the description and illustrations have been made by way of example only. Numerous changes in the details of construction, combination, and arrangement of parts and operations may be made. Accordingly, such changes are intended to be included within the scope of the disclosure, the protected scope of which is defined by the claims.

What is claimed is:

1. A method of designing a structural portion of a vehicular component, the method comprising:
providing a three-dimensional (3D) noise tensor and at least one desired property of the vehicular component;
entering the tensor and the at least one desired property as input into a 3D denoising-diffusion model;
estimating noise within the 3D noise tensor via the 3D denoising-diffusion model as an output;
removing noise from the 3D noise tensor based on the estimated noise;
generating the structural portion of the vehicular component including a 3D cellular structure having the at least one desired property based on the denoised tensor; and
adapting design of the vehicular component based on the generated structural portion.

2. The method of claim 1, wherein providing the 3D noise tensor includes providing a tensor having at least partial diffusion.

3. The method of claim 1, wherein the at least one desired property includes at least one definitional parameter.

4. The method of claim 3, wherein the at least one definitional parameter includes at least one of volume fraction and strength.

5. The method of claim 4, wherein the at least one definitional parameter includes a base shape of the structural portion.

6. The method of claim 3, wherein the at least one desired property is provided as a conditional vector having concatenated scalars defining the at least one definitional parameter.

7. The method of claim 6, wherein the conditional vector is a float vector.

8. The method of claim 1, wherein the 3D noise tensor is a 3D Gaussian noise tensor.

9. The method of claim 8, wherein estimating noise and removing noise comprise iteratively estimating and removing noise for each time step based on a predetermined noise distribution.

10. The method of claim 1, wherein the 3D denoising-difussion model is defined as a 3D residual U-net.

11. The method of claim 1, wherein providing the 3D noise tensor includes providing a voxelized tensor and adding noise.

12. The method of claim 11, wherein providing the 3D noise tensor includes converting a finite element mesh of a known cellular solid structure into a 3D voxelized structure and generating the 3D noise tensor as a voxelized tensor based on the 3D voxelized structure.

13. A system for vehicular component design, the system comprising:
a control system including at least one processor configured for executing instructions stored on memory to conduct operations including:
providing a three-dimensional (3D) noise tensor and at least one desired property of the vehicular component;
entering the tensor and the at least one desired property as input into a 3D denoising-diffusion model;
estimating noise within the 3D noise tensor via the 3D denoising-diffusion model as an output;
removing noise from the 3D noise tensor based on the estimated noise;
generating the structural portion of the vehicular component including a 3D cellular structure having the at least one desired property based on the denoised tensor; and
adapting design of the vehicular component based on the generated structural portion.

14. The system of claim 13, wherein providing the 3D noise tensor includes providing a tensor having at least partial diffusion.

15. The system of claim 13, wherein the at least one desired property includes at least one definitional parameter.

16. The system of claim 15, wherein the at least one definitional parameter includes at least one of volume fraction and strength.

17. The system of claim 16, wherein the at least one definitional parameter includes a base shape of the structural portion.

18. The system of claim 15, wherein the at least one desired property is provided as a conditional vector having concatenated scalars defining the at least one definitional parameter.

19. The system of claim 18, wherein the conditional vector is a float vector.

20. The system of claim 13, wherein estimating noise and removing noise comprise iteratively estimating and removing noise for each time step based on a predetermined noise distribution.
